(19) United States
(12) Patent Application Publication
(10) Pub. No.: US 2007/0141757 A1
(43) Pub. Date: Jun. 21, 2007

(54) Method of manufacturing flexible wiring substrate and method of manufacturing electronic component mounting structure

(75) Inventor: Tomohiro Nomura, Nagano (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: SHINKO ELECTRIC INDUSTRIES CO., LTD., Nagano-shi (JP)

(21) Appl. No.: 11/600,104

(22) Filed: Nov. 16, 2006

(30) Foreign Application Priority Data
Dec. 20, 2005 (JP) 2005-366491

(51) Int. Cl. H01L 21/00

(52) U.S. Cl. 438/125; 257/E21.505

(57) ABSTRACT

A method of manufacturing a flexible wiring substrate of the present invention includes the steps of preparing a tape-like substrate composed of a resin layer and a reinforcing metal layer provided on its lower surface, then forming a via hole whose depth reaches the reinforcing metal layer by processing the resin layer of the tape-like substrate by the laser, and then forming a wiring pattern which is connected to the reinforcing metal layer through the via hole on the resin layer by the semi-additive process, wherein the reinforcing metal layer is patterned to constitute a connection pad connected to the wiring pattern or is removed.

### CROSS-REFERENCE TO RELATED APPLICATIONS

This application is based on and claims priority of Japanese Patent Application No. 2005-366491 filed on Dec. 20, 2005, the entire contents of which are incorporated herein by reference.

### BACKGROUND OF THE INVENTION

1. Field of the Invention

The present invention relates to a method of manufacturing a flexible wiring substrate and a method of manufacturing an electronic component mounting structure and, more particularly, the method of manufacturing the flexible wiring substrate that is applicable to a tape package such as a tape BGA, a tape CSP, or the like, and the method of manufacturing the electronic component mounting structure for mounting an electronic component onto the wiring substrate.

2. Description of the Related Art

In the prior art, there are the tape packages such as the tape BGA (Ball Grid Array), the tape CSP (Chip Size Package), etc. using the polyimide tape as the substrate. In an example of a method of manufacturing the tape package in the prior art, as shown in FIG. 1A, first, a polyimide tape 100 on both surface sides of which an upper Cu layer 102a and a lower Cu layer 102b are provided respectively is prepared. Then, as shown in FIG. 1B, a dry film resist 104 (etching resist) in which an opening portion 104x is provided is formed on the upper Cu layer 102a. Then, an opening portion 102x is formed in the upper Cu layer 102a by wet-etching the upper Cu layer 102a through the opening portion 104x.

Then, as shown in FIG. 1C, the dry film resist 104 is removed.

Then, as shown in FIG. 1D, the polyimide tape 100 is processed by the laser through the opening portion 102x while utilizing the upper Cu layer 102a, in which the opening portion 102x is provided, as a conformal mask. Thus, a via hole 100x having a depth that reaches the lower Cu layer 102b is formed.

Then, as shown in FIG. 1E, a seed layer (not shown) is formed in the via hole 100x and on the upper Cu layer 102a. Then, an upper metal plating layer 106a connected to the lower Cu layer 102b through the via hole 100x is formed on the seed layer by the electroplating. At this time, a lower metal plating layer 106b is also formed on the lower Cu layer 102b.

Then, as shown in FIG. 1F, a dry film resist 105a is formed to be patterned on the upper metal plating layer 106a. Then, the upper metal plating layer 106a, the seed layer, and the upper Cu layer 102a are wet-etched by using the dry film resist 105a as a mask, and then the dry film resist 105a is removed. Similarly, a dry film resist 105b is formed on the lower metal plating layer 106b. Then, the lower metal plating layer 106b and the lower Cu layer 102b are etched, and then the dry film resist 105b is removed. Accordingly, as shown in FIG. 1G, an upper wiring pattern 108a composed of the upper Cu layer 102a, the seed layer (not shown), and the upper metal plating layer 106a is formed on an upper surface of the polyimide tape 100. Also, a lower wiring pattern 108b composed of the lower Cu layer 102b and the lower metal plating layer 106b is formed on a lower surface of the polyimide tape 100.

With the above, the upper wiring pattern 108a and the lower wiring pattern 108b connected mutually through the via hole 100x are formed on both surface sides of the polyimide tape 100 respectively.

As the technology associated with such tape package, in Patent Literature 1 (Patent Application Publication (KOKAI) 2004-363169), the method of forming the multi-layered wiring layer on the tape-like carrier and then removing the tape-like carrier is set forth.

Also, in Patent Literature 2 (Patent Application Publication (KOKAI) Hei 10-178271), the method of forming the connection holes by making up the photosensitive organic polymer material, then forming the insulating layer by curing the polymer material, then filling a copper in the connection holes by the plating method, and then forming the wirings on the insulating layer is set forth.

Also, in Patent Literature 3 (Patent Application Publication (KOKAI) 2002-190543), the method of forming the multi-layered wiring layer on the long flexible base material that the wiring layers are provided on the polyimide tape is set forth.

Also, in Patent Literature 4 (Patent Application Publication (KOKAI) Hei 9-283925), the method of forming the metal layer in the bump forming recesses provided in the metal plate, then forming the multi-layered wiring layer thereon, then mounting the semiconductor chip, and then exposing the bumps from the lower surface side by removing the metal plate is set forth.

In the prior art explained in FIGS. 1A to 1G, since the wiring patterns are formed by the so-called subtractive process, the metal layer having a relatively thick (about 18 μm) must be wet-etched in the step of forming the conformal mask that defines a diameter of the via hole (FIGS. 1B and 1C) and the step of forming the wiring pattern (FIGS. 1F and 1G). For this reason, the wiring pattern is formed to move inward from the pattern of the dry film resist. Therefore, it is difficult to form the via hole and the wiring pattern at a fine pitch (for example, 30 μm pitch (line:space=15:15 μm)).

In addition, nowadays, an increase in the number of layers of the multi-layered wiring is requested, and in the prior art, it is supposed that the multi-layered wiring layer must be formed on both surface sides of the polyimide tape. In this case, since the patterning step becomes complicated, an extreme technical difficulty arises.

### SUMMARY OF THE INVENTION

It is an object of the present invention to provide a method of manufacturing a flexible wiring substrate and a method of manufacturing an electronic component mounting structure, in which it is capable of easily responding to the progress of a fine pitch of via holes and wiring patterns and to a multi-layered structure.

The present invention is concerned with a flexible wiring substrate manufacturing method, which includes the steps of preparing a tape-like substrate composed of a resin layer and a reinforcing metal layer provided on a lower surface of the resin layer; forming a via hole whose depth reaches the reinforcing metal layer, by processing the resin layer of the tape-like substrate; forming a seed layer in the via hole and the resin layer; forming a resist film in which an opening portion is provided in an area containing the via hole on the seed layer; forming a metal layer from the via hole to the opening portion of the resist film by an electroplating utilizing the seed layer as a plating power feeding layer; removing the resist film; and forming a wiring pattern, which is connected to the reinforcing metal layer through the via hole, on the resin layer by etching the seed layer using the metal layer as a mask.

In the present invention, first, the tape-like substrate composed of the resin layer (polyimide, or the like) and the reinforcing metal layer (copper, or the like) provided on the lower surface of the resin layer is prepared. Since the reinforcing metal layer is provided to the lower surface side of the tape-like substrate, expansion and contraction of the substrate can be suppressed while this substrate is carried to various manufacturing systems by the reel-to-reel system and also trouble seldom occurs in carrying the substrate.

Then, the via hole having a depth that reaches the reinforcing metal layer is formed by preferably processing directly the resin layer of the tape-like substrate by the laser. In the present invention, since the resin layer can be processed directly by the laser not to use the conformal mask, the via holes can be formed at a narrow pitch. Then, a predetermined built-up wiring layer connected to the reinforcing metal layer through the via hole is formed on the resin layer by the semi-additive process. Because the semi-additive process is employed, the wiring patterns can be formed at a fine pitch on the tape-like substrate. In addition, expansion and contraction of the substrate can be suppressed by employing the tape-like substrate on which the reinforcing metal layer is provided. As a result, the built-up wiring layer can be formed in a multi-layered fashion such that the via hole and the wiring pattern are aligned with each other at high precision.

Then, according to the use of the wiring substrate, the connection pads connected to the wiring pattern are formed by patterning the reinforcing metal layer, or the lower surface of the wiring pattern in the via hole is exposed by removing the reinforcing metal layer.

When the electronic component is mounted on the flexible wiring substrate according to the present invention, the electronic component (semiconductor chip) can be connected and mounted onto the uppermost layer of the built-up wiring layer in a state that the reinforcing metal layer is provided on the overall back surface. Then, the reinforcing metal layer is patterned or removed. According to such steps, the substrate is not affected by a warp and also conveyance and handling of the substrate can be simplified. Therefore, the electronic component can be mounted over the tape-like substrate with good reliability.

As described above, the present invention can easily respond to progress in a fine pitch of via holes and wiring patterns and to a multi-layered structure in the manufacture of the flexible wiring substrate.

### BRIEF DESCRIPTION OF THE DRAWINGS

FIGS. 1A to 1G are sectional views showing a method of manufacturing a tape package in the prior art;

FIGS. 2A to 2I are sectional views showing a method of manufacturing a flexible wiring substrate according to a first embodiment of the present invention;

FIGS. 3A to 3C are sectional views showing a method of manufacturing a flexible wiring substrate according to a variation of the first embodiment of the present invention;

FIGS. 4A to 4C are sectional views showing a method of manufacturing a first electronic component mounting structure according to a second embodiment of the present invention;

FIG. 5 is a sectional view showing a second electronic component mounting structure according to the second embodiment of the present invention;

FIGS. 6A and 6B are sectional views showing a method of manufacturing a third electronic component mounting structure according to the second embodiment of the present invention; and

FIG. 7 is a sectional view showing a fourth electronic component mounting structure according to the second embodiment of the present invention.

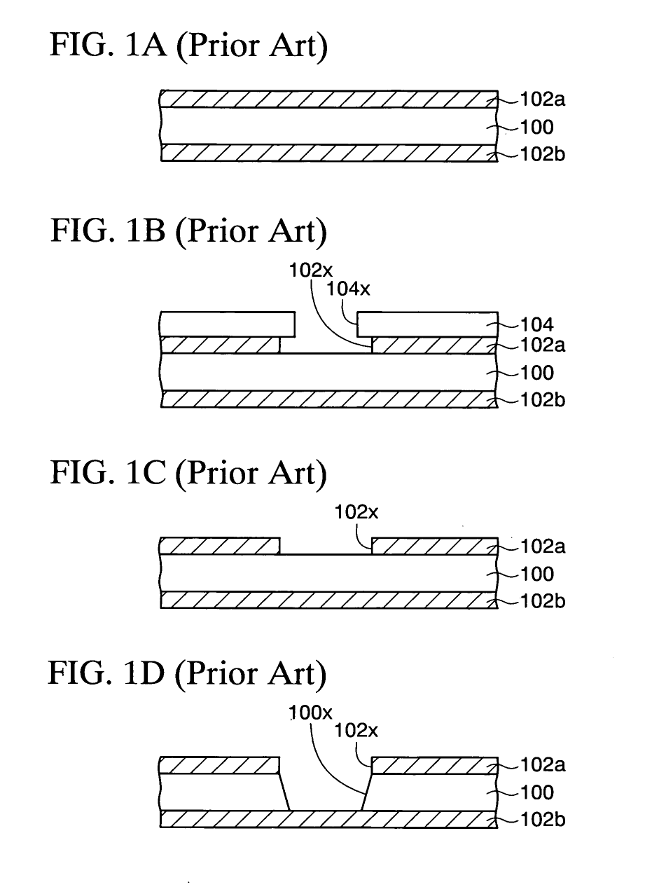

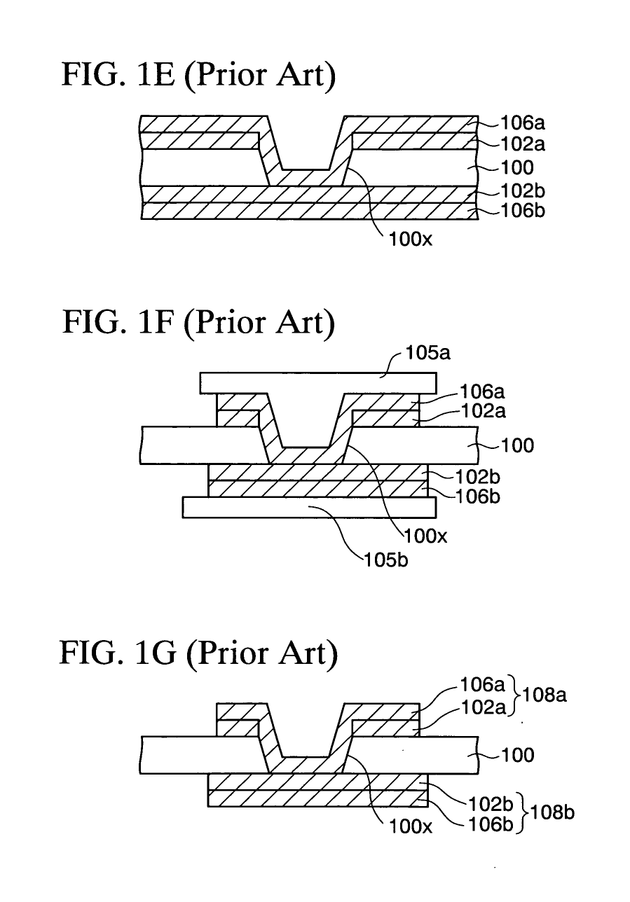

### DETAILED DESCRIPTION OF THE PREFERRED EMBODIMENTS

Embodiments of the present invention will be explained with reference to the accompanying drawings hereinafter.

### First Embodiment

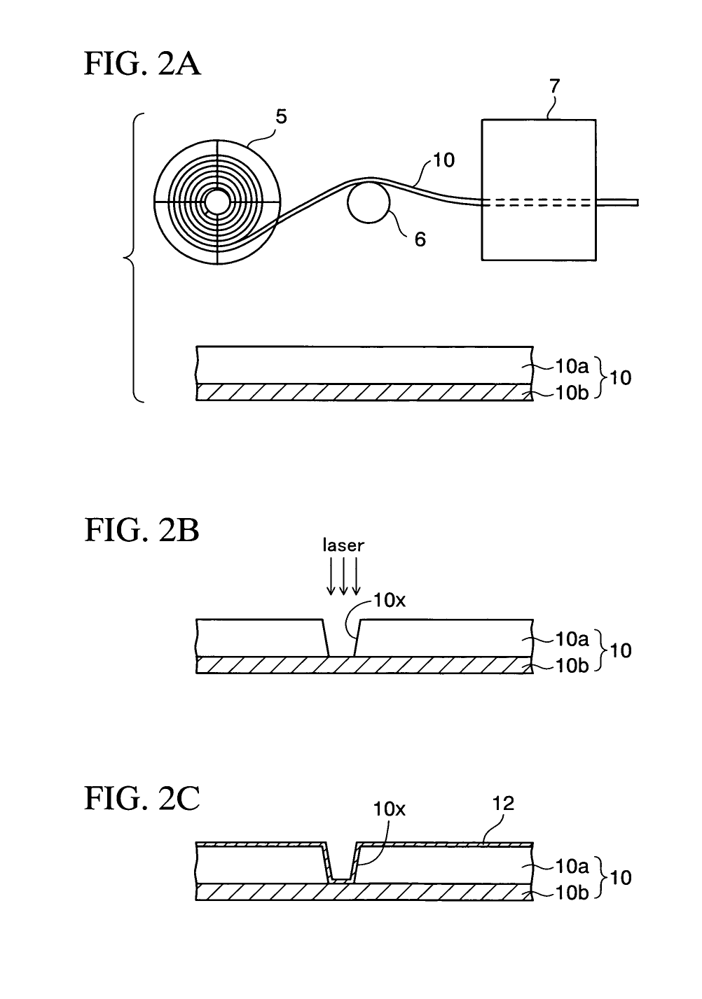

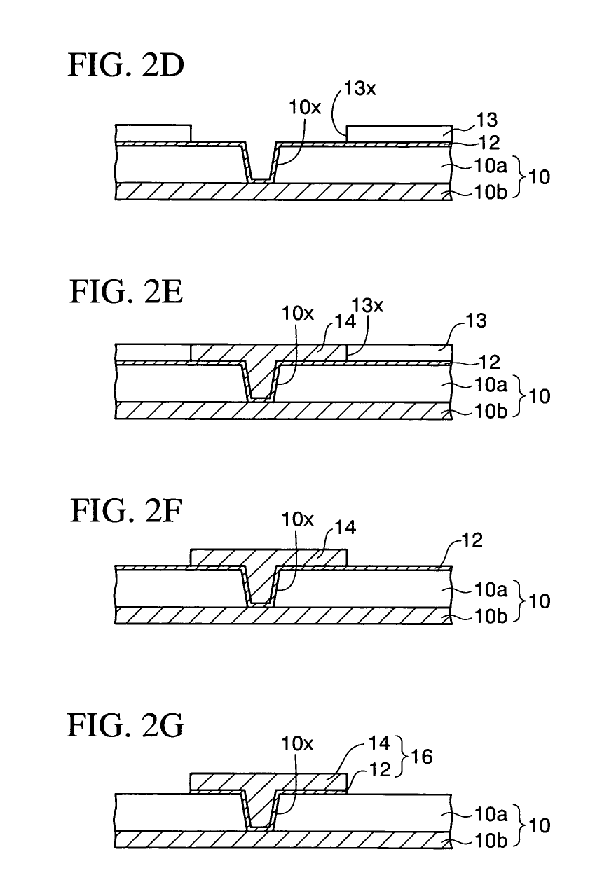

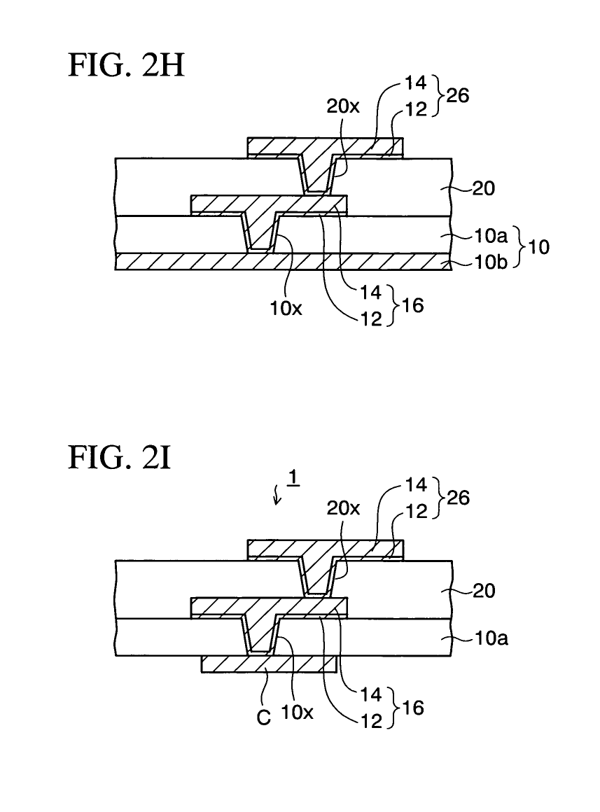

FIGS. 2A to 2I are sectional views showing a method of manufacturing a flexible wiring substrate according to a first embodiment of the present invention. In a method of manufacturing a flexible wiring substrate according to the first embodiment of the present invention, as shown in an upper view of FIG. 2A, first, a long tape-like substrate 10 which is pulled out from a reel (winding member) 5 and is carried in the longitudinal direction is prepared. As shown in a lower view of FIG. 2A, the tape-like substrate 10 is composed of a resin layer 10a and a reinforcing metal layer 10b provided on a lower surface of the resin layer 10a. For example, the resin layer 10a is formed of a polyimide layer whose film thickness is about 25 μm, and the reinforcing metal layer 10b is formed of a copper foil whose film thickness is 15 to 18 μm.

The tape-like substrate 10 is pulled out from the reel 5 and is carried into various manufacturing systems 7 (reel-to-reel system) in a state that a tension (expanding process) is applied to the substrate by a roller 6, and then wiring patterns, the resin layer, etc. are formed on the tape-like substrate 10. The tape-like substrate 10 has both flexibility and some rigidity because the reinforcing metal layer 10b is provided to its lower surface side. Thus, expansion and contraction of the substrate can be suppressed while this substrate is carried to various manufacturing systems 7 by the reel-to-reel system and also trouble seldom occurs in carrying the substrate. Also, because the reinforcing metal layer 10b is provided, there is the advantage such that the resin layer 10a can be thinned.

Then, as shown in FIG. 2B, a predetermined portion of the resin layer 10a of the tape-like substrate 10 is processed directly by the laser. Thus, a first via hole 10x having a depth that reaches the reinforcing metal layer 10b is formed. Since the via hole is formed by direct laser processing without use of the conformal mask, the present embodiment can easily respond to the finer pitch (pitch: 30 μm (via diameter: 15 μm) or less) of the first via hole 10x. In addition, since the reinforcing metal layer 10b is provided on the lower surface side of the tape-like substrate 10, expansion and contraction of the tape-like substrate 10 can be suppressed unlike the case where only the polyimide tape is used. Therefore, alignment precision can be improved and also the first via hole 10x can be formed in a desired position.

In addition to the laser processing, the method of forming a resist film, in which the opening portion is provided, on the resin layer 10a and then etching the resin layer 10a by RIE while using the resist film as a mask may be employed. At that time, similarly the first via holes 10x can be at a fine pitch.

Alternatively, a photosensitive resin such as a photosensitive polyimide resin and the like is used as the resin layer 10a, and the first via hole 10x may be formed by the photolithography process.

Then, as shown in FIG. 2C, a seed layer 12 made of copper, or the like and having a film thickness of 1 μm or less is formed in the first via hole 10x and on the resin layer 10a by the electroless plating or the sputter method. Then, as shown in FIG. 2D, a resist film 13 in which an opening portion 13x is provided in a portion where the wiring pattern is formed is formed on the seed layer 12. The resist film 13 may be formed of a dry film resist or may be formed by coating a liquid resist. Then, as shown in FIG. 2E, a metal layer 14 made of copper, or the like and having a film thickness of 15 to 18 μm is formed in an area extending from the inside of the first via hole 10x to the opening portion 13x of the resist film 13 by the electroplating that utilizes the seed layer 12 as the plating power feeding layer. At this time, the reinforcing metal layer 10b as well as the seed layer 12 can be used as the plating power feeding layer.

Then, as shown in FIG. 2F, the seed layer 12 is exposed by removing the resist film 13. Then, as shown in FIG. 2G, the seed layer 12 is etched by the wet etching while using the metal layer 14 as a mask. Accordingly, a first wiring pattern 16 which is composed of the seed layer 12 and the metal layer 14 and is connected electrically to the reinforcing metal laye 10b via the first via hole 10x is formed on the resin layer 10a.

As described above, in the present embodiment, the first wiring pattern 16 is formed on the tape-like substrate 10 by the semi-additive process. Therefore, unlike the subtractive process, there is no need to etch the metal layer having a thick film thickness (about 18 μm) by the wet etching, and the wiring pattern can be obtained by wet-etching the seed layer 12 having a thin film thickness (1 μm or less). Hence, the first wiring pattern 16 having a line width that substantially corresponds to the opening portion 13x of the resist film 13 can be formed. Because such wiring forming method can be employed, the wiring pattern can be easily formed at a 30 μm pitch (line:space=15:15 μm) or less.

Also, since the reinforcing metal layer 10b is provided on the lower surface side of the tape-like substrate 10, expansion and contraction of the substrate can be suppressed in forming the first wiring pattern 16. Therefore, the first wiring pattern 16 can be formed in a state that such pattern is aligned with the first via hole 10x at high precision.

Then, as shown in FIG. 2H, a upper resin layer 20 for covering the first wiring pattern 16 and the resin layer 10a is formed, and then the upper resin layer 20 is processed by the laser similar to the method of forming the first via hole 10x. Thus, a second via hole 20x having a depth that reaches the first wiring pattern 16 is formed. Also, a second wiring pattern 26 which is composed of the seed layer 12 and the metal layer 14, and is connected electrically to the first wiring pattern 16 via the second via hole 20x, is formed on the upper resin layer 20 by the similar method to the above semi-additive method.

Now, in the present embodiment, a mode where the two-layered built-up wiring layer is formed on the tape-like substrate 10 is illustrated. But an n-layered (n is an integer of 1 or more) built-up wiring layer may be formed by using the semi-additive process.

Also, in the state in FIG. 2H, a solder resist film that exposes pad portions of the second wiring pattern 26 may be provided on the upper resin layer 20 and the second wiring pattern 26.

In the present embodiment, the multi-layered wiring substrate can be obtained by stacking the wiring pattern on one surface side of the tape-like substrate 10. As a result, the film forming step and the patterning step can be simplified rather than the method of stacking the wiring pattern on both surface sides of the substrate, and reduction in a production cost can be achieved.

Then, as shown in FIG. 2I, a resist film (not shown) is formed to be patterned on the reinforcing metal layer 10b on the lower surface side of the tape-like substrate 10, and then the reinforcing metal layer 10b is wet-etched by using the resist film as a mask. Thus, a connection pad C connected to the first wiring pattern 16 is formed on the lower surface side of the resin layer 10a. Since the connection pad C is formed on the resin layer 10a, the resin layer 10a may be formed of a resin for a solder resist.

The subtractive process is employed in the step of forming the connection pad C, but the connection pad C is the electrode on which an external connection terminal such as a solder ball, or the like is provided. Therefore, there is no necessity to form the connection pad C as a fine pattern like the first and second wiring patterns 16, 26.

Here, the built-up wiring layer connected to the connection pad C can be formed on the lower surface side of the tape-like substrate 10, as the case may be. Also, nickel, gold, or the like may be plated on the connection pad C.

With the above, a flexible wiring substrate 1 of the present embodiment can be obtained.

As explained above, in the method of manufacturing the flexible wiring substrate according to the present embodiment, first, the tape-like substrate 10 composed of the resin layer 10a and the reinforcing metal layer 10b provided on the lower surface of the resin layer 10a is prepared. Since the reinforcing metal layer 10b is provided on the lower surface of the resin layer 10a of the tape-like substrate 10, expansion and contraction of the substrate can be suppressed while the tape-like substrate 10 is carried to various manufacturing systems by the reel-to-reel system, and also the trouble is hard to occur during the conveyance.

Then, the first via hole 10x is formed by processing the resin layer 10a of the tape-like substrate 10 by means of the laser. In the present embodiment, since the resin layer 10a is processed directly by the laser not to use the conformal mask, the first via holes 10x can be formed at a narrow pitch. Then, the predetermined built-up wiring layer (the first and second wiring patterns 16, 26) connected to the reinforcing metal layer 10b through the first via hole 10x is formed by the semi-additive process. Since the semi-additive process is employed, the wiring patterns can be formed at a fine pitch on the tape-like substrate 10. In addition, since the tape-like substrate 10 in which the reinforcing metal layer 10b is provided is employed, expansion and contraction of the substrate can be suppressed. Accordingly the up wiring layer can be formed in a multi-layered fashion such that the via hole and the wiring pattern are aligned with each other at high precision.

Further, since the reinforcing metal layer 10b is provided on the lower surface of the resin layer 10a, a film thickness of the resin layer 10a can be reduced. Therefore, a reduction in thickness of the flexible wiring substrate can be achieved.

Next, a method of manufacturing a flexible wiring substrate according to a variation of the first embodiment of the present invention will be explained hereunder. A mode where the reinforcing metal layer 10b is removed finally from the tape-like substrate 10 is given by the manufacturing method according to this variation.

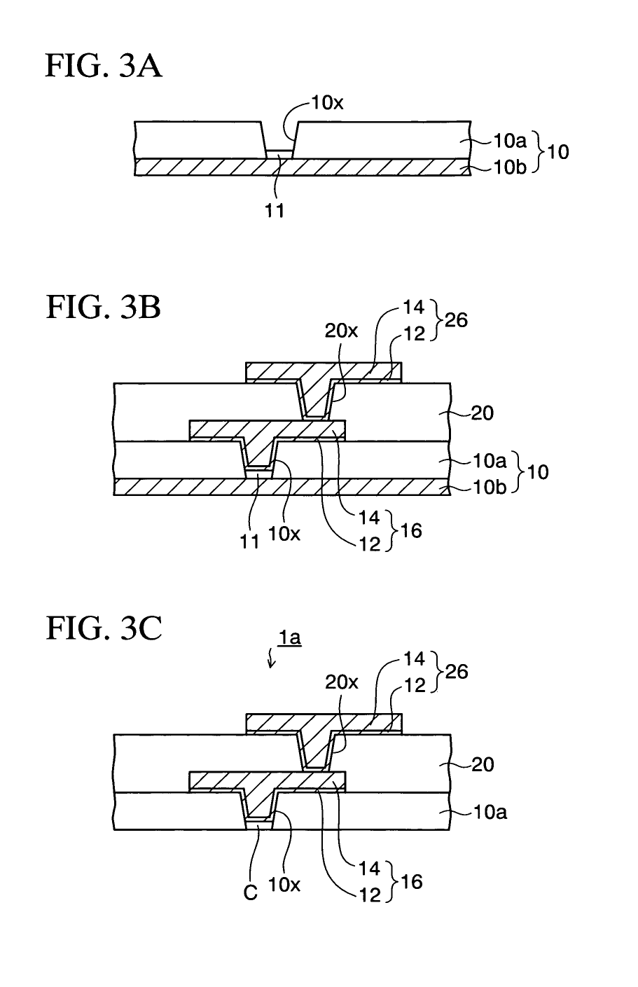

As shown in FIG. 3A, the first via hole 10x is formed in the resin layer 10a of the tape-like substrate 10 by the above manufacturing method, and then a pad plating layer 11 is formed on the reinforcing metal layer 10b exposed from a bottom surface of the first via hole 10x. As the pad plating layer 11, a gold layer/a nickel layer, a gold layer/a palladium layer/a nickel layer, or the like, which are stacked in sequence from the bottom, is employed.

Then, the step of forming the seed layer 12 (FIG. 2C) to the step of forming the second wiring pattern 26 (FIG. 2H) described above are carried out. Thus, as shown in FIG. 3B, a structure in which the pad plating layer 11 is provided between the reinforcing metal layer 10b and the seed layer 12 on the bottom portion of the first via hole 10x of the structure in FIG. 2H can be obtained. The first wiring pattern 16 is formed to contain the pad plating layer 11.

Then, as shown in FIG. 3C, the pad plating layer 11 (the lower surface of the first wiring pattern 16) is exposed from the bottom surface by removing the reinforcing metal layer 10b by means of wet-etching, or the like to constitute the connection pad C. The pad plating layer 11 made of above metal layer (the lowermost portion is formed of the gold layer) is not dissolved by the wet etching applied in removing the reinforcing metal layer 10b (copper foil). As a result, the reinforcing metal layer 10b is selectively removed from the pad plating layer 11. When the above metal material is employed as the pad plating layer 11, the gold layer is exposed from the lower surface of the connection pad C. In this mode, since the connection pad C can be formed with a fine pattern, the connection pad C can be used as a pad for mounting a semiconductor chip.

With the above, a flexible wiring substrate la according to the variation of the present embodiment is obtained.

### Second Embodiment

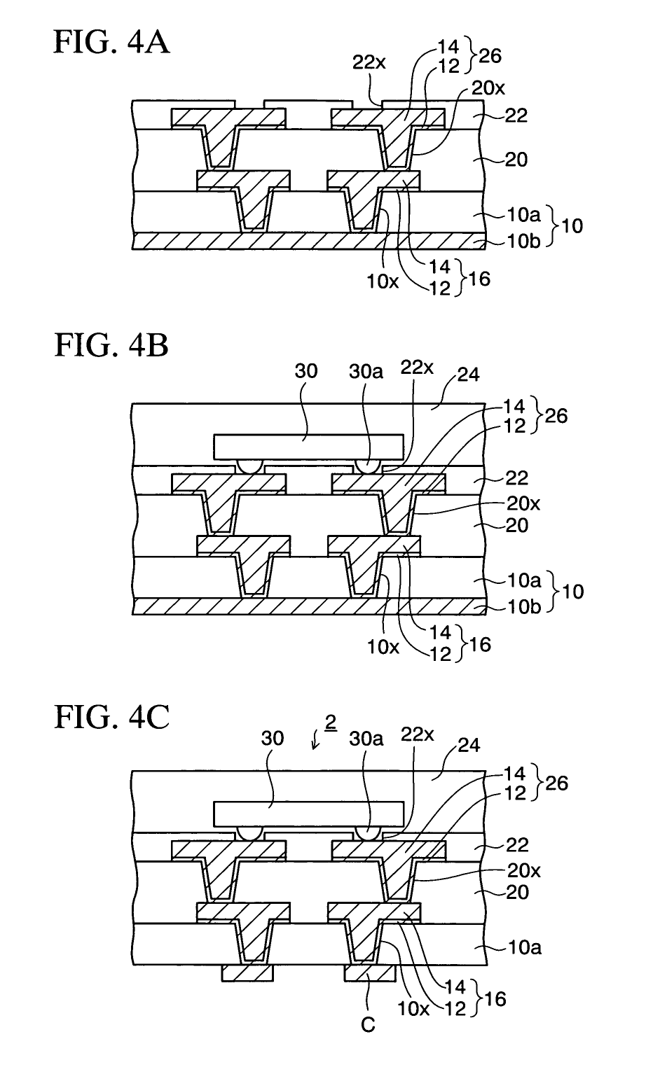

FIGS. 4A to 4C are sectional views showing a method of manufacturing a first electronic component mounting structure according to a second embodiment of the present invention. In the second embodiment, a mode where an electronic component is mounted on the flexible wiring substrate will be explained hereunder, on the base of the technical idea of the manufacturing method of the flexible wiring substrate of the present invention. In the second embodiment, the same reference numerals are affixed to the same elements as the first embodiment and their explanation will be omitted herein.

First, as shown in FIG. 4A, the predetermined built-up wiring layer is formed on the tape-like substrate 10 by the similar method to the first embodiment. In FIG. 4A, like the first embodiment, an example where the first and second wiring patterns 16, 26 are stacked on the tape-like substrate 10 is illustrated. Then, a solder resist film 22 in which an opening portion 22x is provided on the connection portion of the second wiring pattern 26 is formed. Then, a contact layer (not shown) is formed by applying the Ni/Au plating to the second wiring pattern 26 in the opening portion 22x of the solder resist film 22, as the case may be.

Then, as shown in FIG. 4B, bumps 30a of a semiconductor chip 30 are flip-chip connected to the second wiring pattern 26 in the opening portion 22x of the solder resist film 22. Then, a mold resin 24 for filling a clearance formed under the semiconductor chip 30 and also covering the semiconductor chip 30 is formed. In the present embodiment, the semiconductor chip 30 is mounted on the wiring substrate having a state that the reinforcing metal layer 10b is left as the lowermost layer. Therefore, the mounting structure is never affected by a warp and also the conveyance and handling can be made easy. Accordingly the semiconductor chip 30 can be mounted with good reliability.

Then, as shown in FIG. 4C, the reinforcing metal layer 10b on the lower surface side of the tape-like substrate 10 is patterned. Thus, the connection pad C connected to the first wiring pattern 16 is formed. With the above, a first electronic component mounting structure 2 of the present embodiment can be obtained. Actually, a plurality of semiconductor chips are mounted above the tape-like substrate 10, and after the plurality of semiconductor chips are mounted, the tape-like substrate 10 and the mold resin 24 and the like are cut, thereby each electronic component mounting structure 2 is obtained.

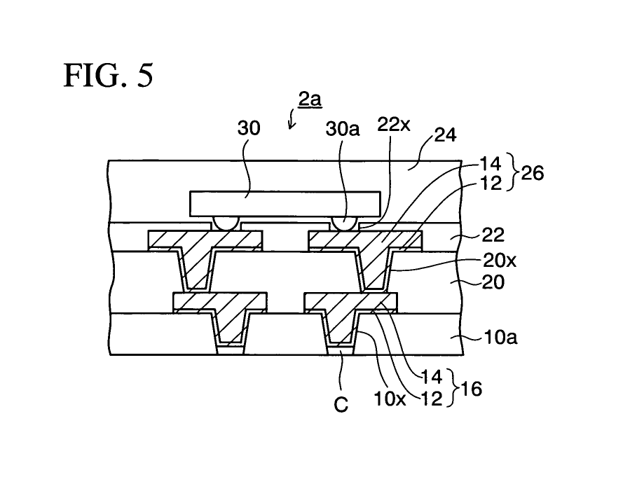

A second electronic component mounting structure according to the second embodiment is shown in FIG. 5. Like the variation of the above first embodiment, the pad plating layer 11 made of the similar metal material is provided between the reinforcing metal layer lob and the seed layer 12 in the first via hole 10x. Then, the pad plating layer 11 is exposed by removing the reinforcing metal layer 10b to constitute the connection pad C. Accordingly, a second electronic component mounting structure 2a of the second embodiment can be obtained. Since remaining manufacturing steps are similar to those of the manufacturing method of the first electronic component mounting structure 2, their explanation will be omitted herein.

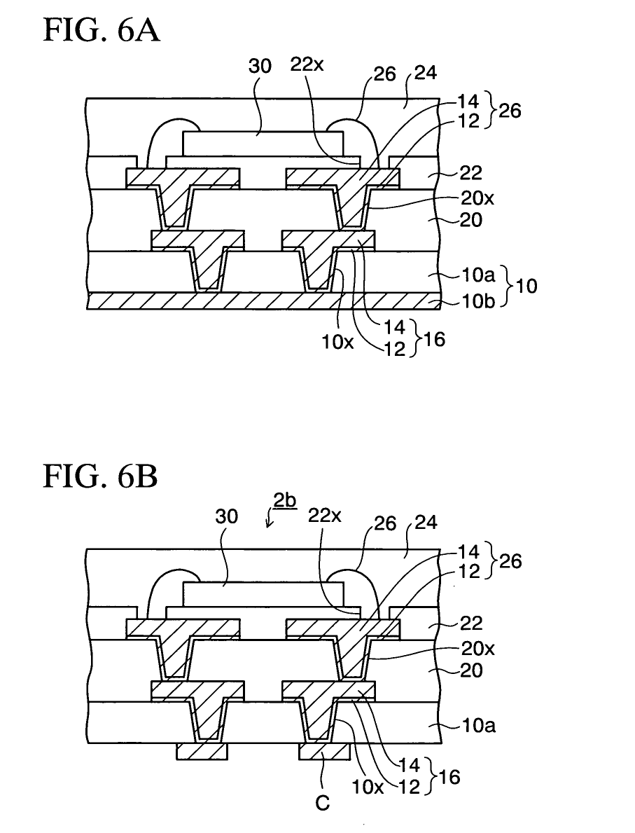

A method of manufacturing third electronic component mounting structure according to the second embodiment of the present invention is shown in FIGS. 6A and 6B. As shown in FIG. 6A, the semiconductor chip 30 is secured onto the solder resist film 22 to direct its connection portion upward, and then the connection portions of the semiconductor chip 30 and the second wiring patterns 26 in the opening portions 22x of the solder resist film 22 are connected electrically mutually via wires 26 by the wire bonding method. Then, the semiconductor chip 30 is sealed with the mold resin 24. Then, as shown in FIG. 6B, the reinforcing metal layer 10b on the lower surface side of the tape-like substrate 10 is patterned to form the connection pad C connected to the first wiring pattern 16. Accordingly, a third electronic component mounting structure 2b of the present embodiment can be obtained.

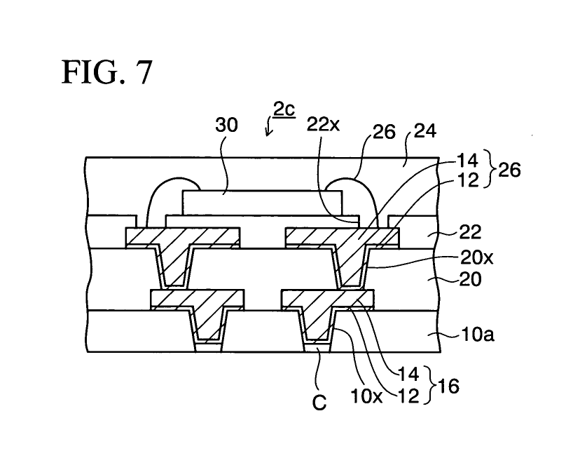

A fourth electronic component mounting structure according to the second embodiment is shown in FIG. 7. Like the second electronic component mounting structure 2a (FIG. 5), a fourth electronic component mounting structure 2c shows such a mode that the pad plating layer 11 is provided between the reinforcing metal layer 10b and the seed layer 12 in the first via hole 10x in FIG. 6A and the pad plating layer 11 is exposed by removing the reinforcing metal layer 10b to constitute the connection pad C. Since remaining manufacturing steps are similar to those of the manufacturing method of the third electronic component mounting structure 2b, their explanation will be omitted herein.

In the present embodiment, the semiconductor chip 30 is mounted on the built-up wiring layer provided on the long tape-like substrate 10, then a resultant structure is sealed with the mold resin 24, then the reinforcing metal layer 10b is patterned or removed, and then the structure is cut away. Thus, individual electronic component mounting structures 2 to 2c (semiconductor devices) can be obtained. Also, the electronic component mounting structures can be cut away in a state that the reinforcing metal layer 10b is left.

Actually, a plurality of semiconductor chips 30 are mounted above the tape-like substrate 10, and after the plurality of semiconductor chips are mounted, the tape-like substrate 10 and the mold resin 24 and the like are cut.

In the example in FIG. 4C and FIG. 6B, the example where the external connecting system is used as LGA (Land Grid Array) type is illustrated and the connection pad C is used as the land. When the external connecting system is used as the BGA (Ball Grid Array) type, and the external connection terminal is provided by mounting the solder ball, or the like on the connection pad C. Also, when the external connecting system is used as the PGA (Pin Grid Array) type, the lead pin is provided on the connection pad C.

Also, in FIG. 4C and FIG. 6B, nickel, gold, or the like may be plated on the connection pad C. Also, the semiconductor chip 30 is illustrated as the electronic component, but various electronic components such as the capacitor component, and the like can be mounted. Also, as the electronic component mounting method, various mounting methods may be employed in addition to the flip-chip bonding and the wire bonding.

What is claimed is:

1. A method of manufacturing a flexible wiring substrate, comprising the steps of:
preparing a tape-like substrate composed of a resin layer and a reinforcing metal layer provided on a lower surface of the resin layer;
forming a via hole whose depth reaches the reinforcing metal layer, by processing the resin layer of the tape-like substrate;
forming a seed layer in the via hole and on the resin layer;
forming a resist film in which an opening portion is provided in an area containing the via hole on the seed layer;
forming a metal layer from the via hole to the opening portion of the resist film by an electroplating utilizing the seed layer as a plating power feeding layer;
removing the resist film; and
forming a wiring pattern, which is connected to the reinforcing metal layer through the via hole, on the resin layer by etching the seed layer using the metal layer as a mask.

2. A method of manufacturing a flexible wiring substrate, according to claim 1, wherein after the step of forming a via hole, a pad plating layer is formed on a bottom surface of the first via hole.

3. A method of manufacturing a flexible wiring substrate, according to claim 1, wherein the tape-like substrate is a long one which is pulled out from a reel and is carried in the longitudinal direction.

4. A method of manufacturing a flexible wiring substrate, according to claim 1, further comprising the step of:
after the step of forming the wiring pattern,
forming a connection pad connected to the wiring pattern on a lower surface side of the resin layer by patterning the reinforcing metal layer.

5. A method of manufacturing a flexible wiring substrate, according to claim 1, further comprising the step of:
after the step of forming the wiring pattern,
exposing a lower surface of the wiring pattern in the via hole by removing the reinforcing metal layer.

6. A method of manufacturing a flexible wiring substrate, according to claim 1, wherein the via hole is formed by processing directly the resin layer by a laser not to interpose a mask in the step of forming the via hole.

7. A method of manufacturing a flexible wiring substrate, according to claim 1, further comprising the step of:
after the step of forming the wiring pattern,
forming an n-layered (n is an integer of 1 or more) built-up wiring layer connected to the wiring pattern on an upper surface side of the tape-like substrate by a same method as a forming method of the wiring pattern.

8. A method of manufacturing a flexible wiring substrate, according to claim 1, wherein the resin layer is made of polyimide, and the reinforcing metal layer is made of a copper foil.

9. A method of manufacturing an electronic component mounting structure, comprising the steps of:
preparing a tape-like substrate composed of a resin layer and a reinforcing metal layer provided on a lower surface of the resin layer;
forming a via hole whose depth reaches the reinforcing metal layer, by processing the resin layer of the tape-like substrate;
forming a seed layer in the via hole and the resin layer;
forming a resist film in which an opening portion is provided in an area containing the via hole on the seed layer;
forming a metal layer from the via hole to the opening portion of the resist film by an electroplating utilizing the seed layer as a plating power feeding layer;
removing the resist film;
forming a wiring pattern, which is connected to the reinforcing metal layer through the via hole, on the resin layer by etching the seed layer using the metal layer as a mask; and
mounting an electronic component connected to the wiring pattern.

10. A method of manufacturing an electronic component mounting structure, according to claim 9, wherein after the step of forming a via hole, a pad plating layer is formed on a bottom surface of the first via hole.

11. A method of manufacturing an electronic component mounting structure, according to claim 9, further comprising the step of:
after the step of mounting the electronic component,
forming a connection pad connected to the wiring pattern on a lower surface side of the resin layer by patterning the reinforcing metal layer.

12. A method of manufacturing an electronic component mounting structure, according to claim 9, further comprising the step of:
after the step of mounting the electronic component,
exposing a lower surface of the wiring pattern in the via hole by removing the reinforcing metal layer.
